(19) United States
(12) Patent Application Publication
(10) Pub. No.: US 2014/0175538 A1
(43) Pub. Date: Jun. 26, 2014

(54) SEMICONDUCTOR APPARATUS AND FABRICATION METHOD THEREOF

(71) Applicant: SK HYNIX INC., Gyeonggi-do (KR)

(72) Inventors: Hyun Seok KANG, Gyeonggi-do (KR); Jeong Tae KIM, Gyeonggi-do (KR)

(73) Assignee: SK HYNIX INC., Gyeonggi-do (KR)

(21) Appl. No.: 13/846,209

(22) Filed: Mar. 18, 2013

(30) Foreign Application Priority Data
Dec. 26, 2012 (KR) 10-2012-0153456

(51) Int. Cl. H01L 29/66; H01L 29/78

(52) U.S. Cl. CPC H01L 29/66666; H01L 29/7827
USPC 257/329; 438/156

(57) ABSTRACT

A semiconductor apparatus includes a semiconductor substrate and a semiconductor layer extending along the substrate in a first direction and connecting to the semiconductor substrate, the semiconductor layer having a portion that connects to the semiconductor substrate, and a portion that does not connect to the semiconductor substrate and forms an active region floating over the semiconductor substrate. A word line formed on the active region and extends in a direction perpendicular to the first direction. Junction regions formed in the active region at both sides of the word line; and an air gap formed in a floating region between the semiconductor substrate and the active region.

### CROSS-REFERENCES TO RELATED APPLICATION

The present application claims priority under 35 U.S.C. 119(a) to Korean application number 10-2012-0153456, filed on Dec. 26, 2012, in the Korean Intellectual Property Office, which is incorporated herein by reference in its entirety.

### BACKGROUND OF THE INVENTION

1. Technical Field

The inventive concept relates to a semiconductor integrated apparatus, and more particularly, to a semiconductor apparatus and a fabrication method thereof.

2. Related Art

Various researches on improvement of integration density in semiconductor memory apparatuses have been progressed. As an example, there are vertical diodes or vertical transistors.

In vertical switching devices, pillars have to be formed to have a sufficient thickness to improve off-current characteristic or an effective channel length. However, the high height of the pillar causes an aspect ratio to be increased so that the process of forming the device has difficulty and leaning of the pillar occurs. Thus, horizontal channel transistors have been suggested.

To fabricate a horizontal channel transistor, first, a sacrificial layer, having a predetermined thickness, and a first semiconductor layer, having a predetermined depth, are sequentially formed over a semiconductor substrate. The sacrificial layer and the first semiconductor layer include semiconductor material layers having different etch selectivities from each other. For example, the sacrificial layer may include silicon germanium (SiGe) and the first semiconductor layer may include silicon (Si). Both of the sacrificial layer and the first semiconductor layer may be formed through an epitaxial growth method to have a perfect crystalline state.

Next, a photoresist pattern (not shown) is formed on a predetermined region of the first semiconductor layer, and the first semiconductor layer and the sacrificial layer are patterned in the same shape as the photoresist pattern to form a hole exposing a surface of the semiconductor substrate.

After the hole is formed, a native oxide layer is completely removed and a heat treatment is performed at a predetermined temperature in an ambient of hydrogen. Therefore, the first semiconductor layer is flowed to be filled in the hole, and becomes a second semiconductor layer.

After the second semiconductor layer is formed, the second semiconductor layer and the sacrificial layer are patterned in a direction perpendicular to a formation direction of a gate line to confine an active region.

When an active region is confined, a line-shaped gate structure, that is, a word line is formed to a direction perpendicular to the active region, and the sacrificial layer is removed along the exposed surface. An insulating layer is filled in a space from which the sacrificial layer is removed and recessed so that the insulating layer remains on a surface of the semiconductor substrate.

Impurities are implanted into the active region at both sides of the word line to form a source region and a drain.

Here, the insulating layer filled in the portion from which the sacrificial layer is removed may include a material, such as a silicon-on-dielectric (SOD). However, since a space in which the insulating layer is filled, that is, a space below the second semiconductor layer is a space extending to a horizontal direction, the filling of the insulating layer is not easy.

When the sacrificial layer is removed after the gate structure is formed, since a path into which the insulating layer is introduced is formed to be very small less than 10 nm by the gate structure and a spacer deposited to protect the gate structure, the filling of the insulating layer in the space from which the sacrificial layer is removed is very difficult.

A high temperature annealing process for entirely oxidizing the insulating layer is accompanied after the insulating layer is filled in the space from which the sacrificial layer is removed. Since an SOD material constituting the insulating layer contains lots of hydrogen and nitrogen atoms, the SOD is oxidized through the annealing process and the hydrogen and nitrogen atoms have to be exhausted to the outside, so that insulation characteristic may be ensured. However, as described above, since the space in which the insulating layer is to be buried below the second semiconductor layer extends to the horizontal direction and further an exposed portion of the insulating layer burying space is small under a state in which the gate structure is formed, the space has a structure in which a reaction gas is difficult to be exhausted to the outside in the annealing process.

As described above, the reaction gas such nitrogen or hydrogen is not exhausted to the outside, the insulating characteristic of the SOD is degraded and the damages of the semiconductor substrate and second semiconductor layer are caused by the reaction gas which are not exhausted to the outside and thus characteristic and reliability of the device are degraded.

### SUMMARY

According to one aspect of an exemplary implementation, there is provided a semiconductor apparatus. An exemplary semiconductor apparatus may include a semiconductor substrate; a semiconductor layer extending along the substrate in a first direction and connecting to the semiconductor substrate, the semiconductor layer having a portion that connects to the semiconductor substrate, and a portion that does not connect to the semiconductor substrate and forms an active region floating over the semiconductor substrate; a word line formed on the active region and extending in a direction perpendicular to the first direction; junction regions formed in the active region at both sides of the word line; and an air gap formed in a floating region between the semiconductor substrate and the active region.

A method of fabricating an exemplary semiconductor apparatus may include forming a sacrificial layer on a semiconductor substrate; forming a semiconductor layer on the sacrificial layer; forming, through the sacrificial layer, a source post connecting the semiconductor layer to the semiconductor substrate; patterning the semiconductor layer to define an active region extending in a first direction; forming, in a direction perpendicular to the first direction, a gate structure on the active region; removing the sacrificial layer to form a silicon-on-insulating (SOI) region between the semiconductor layer and the semiconductor substrate; and forming an interlayer insulating layer in a space between the gate structure and an adjacent gate structure to form an air gap in the SOI region.

These and other features, aspects, and implementations are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 7B are cross-sectional views illustrating a method of fabricating a, exemplary semiconductor apparatus.

### DETAILED DESCRIPTION

Hereinafter, exemplary implementations will be described in greater detail with reference to the accompanying drawings.

Exemplary implementations are described herein with reference to cross-sectional illustrations that are schematic illustrations of exemplary implementations (and intermediate structures). As such, variations from the shapes of the illustrations as a result, for example, of manufacturing techniques and/or tolerances, are to be expected. Thus, exemplary implementations should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

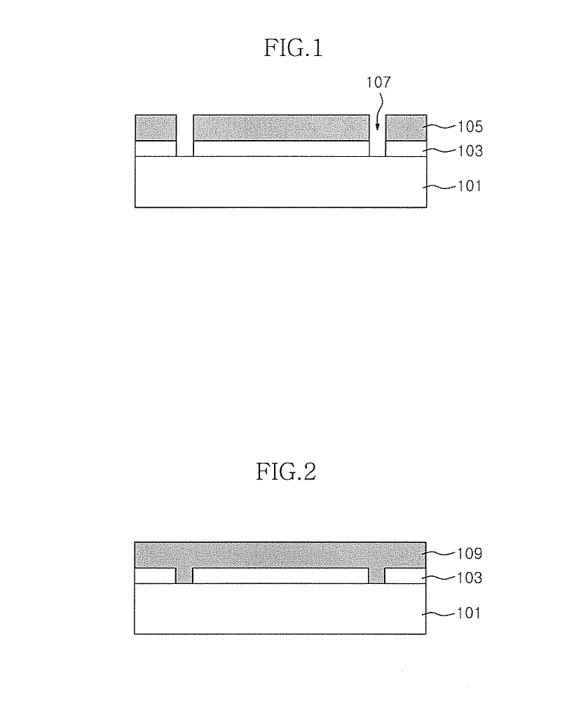

FIGS. 1 to 7B are cross-sectional views illustrating a method of fabricating an exemplary semiconductor apparatus.

First, referring to FIG. 1, a sacrificial layer 103 and a first semiconductor layer 105 are sequentially formed on a semiconductor substrate 101. A photoresist pattern (not shown) is formed on a predetermined portion of the first semiconductor layer 105, and the first semiconductor layer 105 and the sacrificial layer 103 are patterned in the same shape as the photoresist pattern to form a hole 107 exposing a surface of the semiconductor substrate 101.

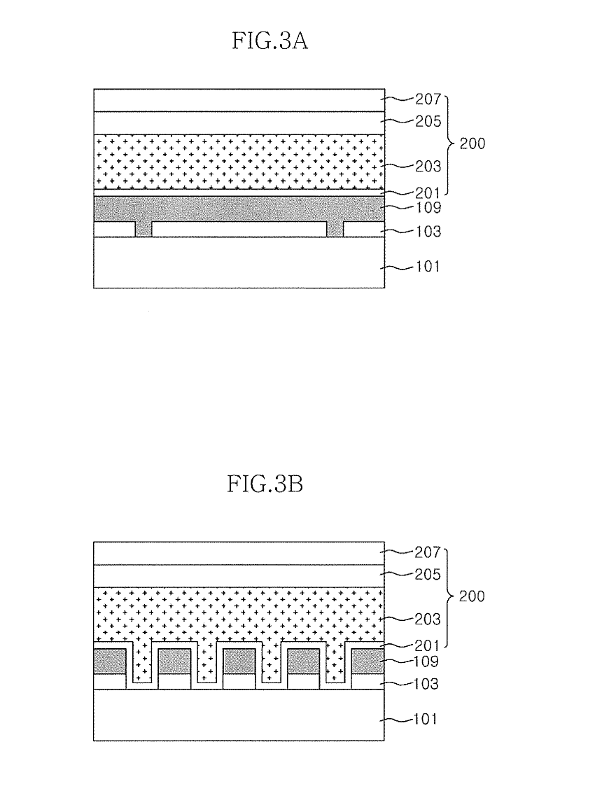

After the hole 107 is formed, a native oxide layer is completely removed and a heat treatment is performed at a predetermined temperature in a hydrogen atmosphere. When the heat treatment is performed at a predetermined temperature in a hydrogen atmosphere, the first semiconductor layer 105 is flowed, and as illustrated in FIG. 2, a second semiconductor layer 109 is formed and fills the hole 107. The semiconductor layer 109 buried the hole 107 may be referred to as a source post and the remaining portion of the second semiconductor layer 109 serves as an active region. After the second semiconductor layer 109 is formed, a hard mask (not shown) is formed in a direction (the same direction as a direction of the device illustrated in FIG. 2) perpendicular to a formation direction of a gate line to be formed in a subsequent process, and the second semiconductor layer 109 and the sacrificial layer 103 are patterned to define an active region.

In an exemplary implementation, a common source region (not shown) may be formed to a predetermined depth in the semiconductor substrate 101 after the defining of the active region. The forming of the common source region may be performed before the forming of the sacrificial layer 103

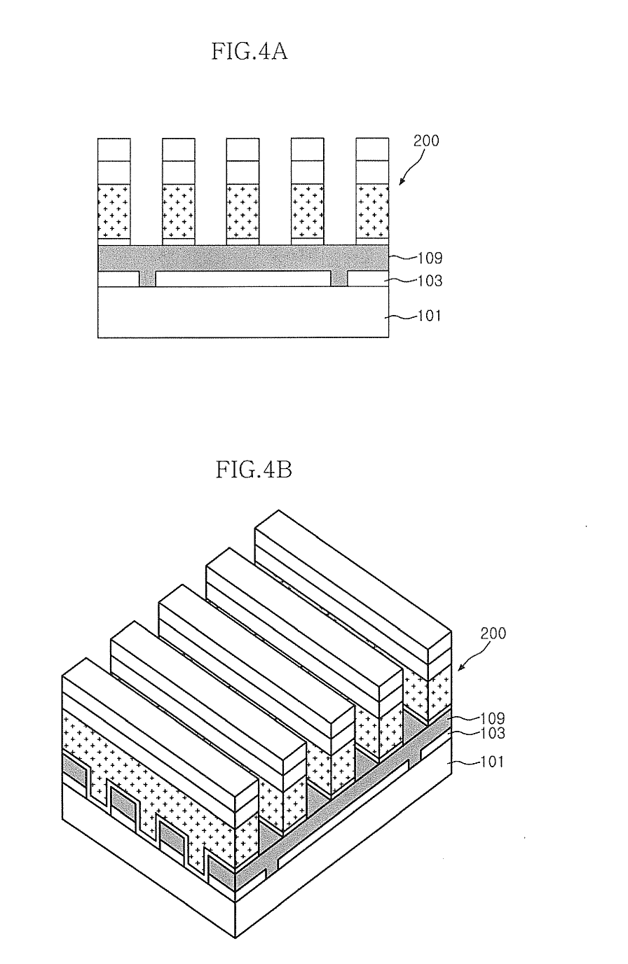

After the defining of the active region, a gate structure 200, that is, a gate insulating layer 201, a gate conductive layer 203, a barrier conductive layer 205, and a hard mask 207 are sequentially formed on the semiconductor substrate, including the defined active region as illustrated in FIGS. 3A and 3B. FIG. 3A is a cross-sectional view in an extending direction of the active region, and FIG. 3B is a cross-sectional view in a direction perpendicular to the active region. The gate structure 200 serves as a word line.

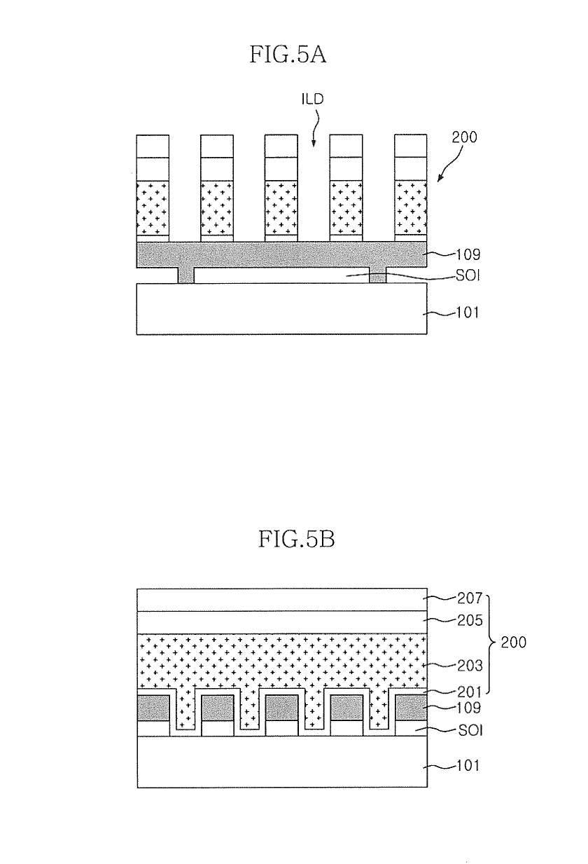

As illustrated in FIGS. 4A and 4B, the gate structure 200 is patterned in the direction perpendicular to the extending direction of the active region. FIG. 4A is a cross-sectional view in the extending direction of the active region and FIG. 4B is a perspective view. It can be seen from FIGS. 4A and 4B that after the patterning of the gate structure 200, the semiconductor substrate 101 is exposed in a space between gate structures 200 and the sacrificial layer 103 is exposed along a side of the semiconductor substrate 101 between the gate structures 200.

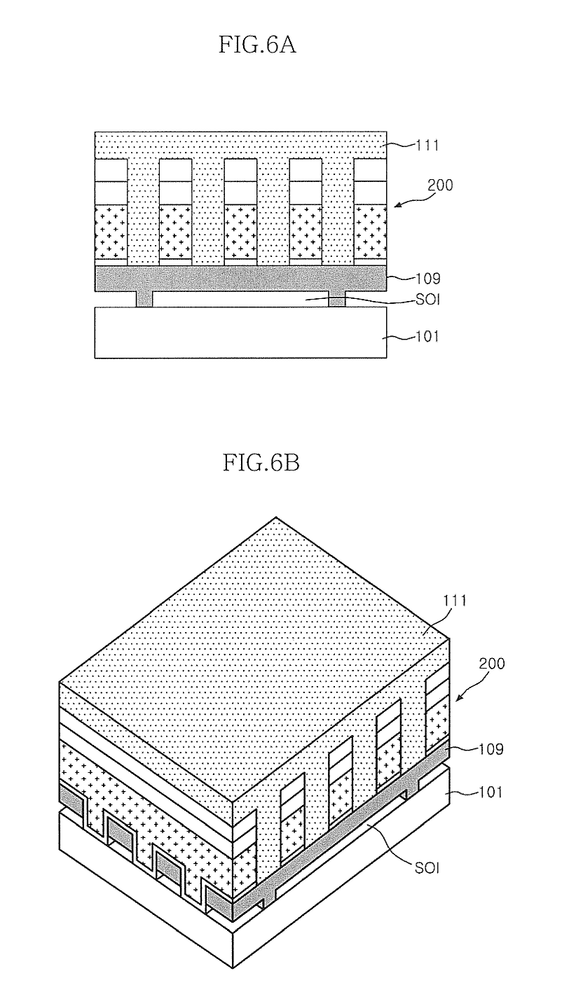

After the patterning of the gate structure 200, a gate spacer (not shown) is formed to protect the gate structure 200. In an exemplary implementation, the gate spacer may be formed to a thickness of about 50 Å to about 100 Å by considering lost in a heat-treatment process for a first interlayer insulating layer 111 (refer to FIGS. 6a and 6b) to be formed in a subsequent process and the gate spacer may be included as a part of the gate structure 200.

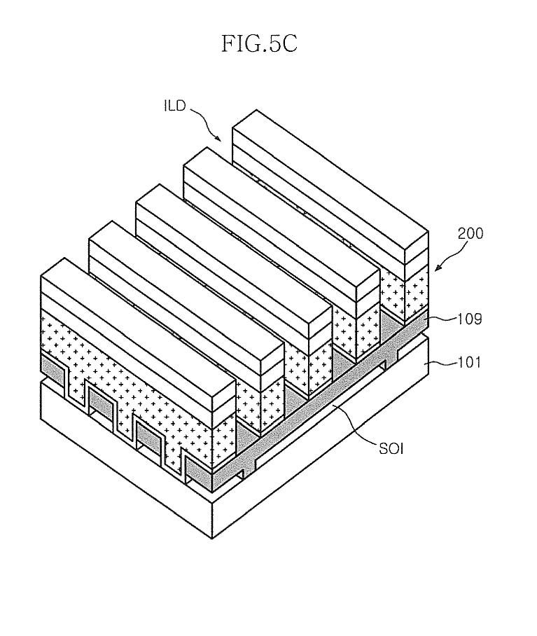

Further, the sacrificial layer 103 is removed along the exposed space between gate structures 200 to form a silicon-on-insulator (SOI) region. FIG. 5A is a cross-sectional view in the extending direction of the active region showing the SOI region, which is formed after the removal of the sacrificial layer 103. FIG. 5B is a cross-sectional view in the extending direction of the gate structure, and FIG. 5C is a perspective view.

It can be seen from FIGS. 5A to 5C that the SOI region extends in a horizontal direction and the space between the gate structures is narrow. Therefore, it is difficult to remove the sacrificial layer 103 from the SOI region, Further, if the gate spacer (not shown) is formed on the gate structure 200, an exposed area to reach the SOI region SOI is further reduced.

Therefore, in the exemplary implementation, a first interlayer insulating layer 111 is not buried in the SOI region. Rather, the first interlayer insulating layer 111 is formed only in a space (interlayer dielectric (ILD)) region between the gate structures 200. It can be seen from FIG. 6A (a cross-sectional view in the extending direction of the active region) and 6B (perspective view) that the first interlayer insulating layer 111 is formed on the semiconductor substrate in which the gate structure 200 is formed using a material having a vertical cap-fill property in which the first interlayer insulating layer 111 does not penetrated into the SOI region.

In an exemplary implementation, the first interlayer insulating layer 111 may include an impurity-doped borophosphosilicate glass (BPSG) oxide layer that is reflowable at a low temperature and has a good gap-fill property. The first interlayer insulating layer 111 may be formed using a sub-atmospheric chemical vapor deposition (SACVD) method having good step coverage. Further, after the first interlayer insulating layer 111 is formed, a wet annealing process may be performed at a temperature of about 700° C. to about 750° C. to prevent device characteristics from being degraded.

If a BPSG oxide layer, which is doped with boron (B) ions and phosphorous (P) ions, is used as the first interlayer insulating layer 111, then the concentrations of the B ions and P ions implanted into the thin film may be in a range of about 4 wt % to about 6 wt % to effectively reflow the BPSG oxide layer in the low temperature wet annealing process. The first interlayer insulating layer 111 may be formed to a thickness of about 1000 Å to be sufficiently buried within the ILD region.

Further, through the low temperature heat treatment process, seams and voids may be removed as well as the first interlayer insulating layer 111 is reflowed. However, since the first interlayer insulating layer 111 is not flowed into the SOI region, an air gap is formed in the SOI region, and the filling of the ILD region is completed.

Since the SOI region is not filled with the first interlayer insulating layer 111 and has an air gap, the SOI region is free from issues, such as gas generated during the heat treatment process (which may occur is a material in the SOI region), or damage of the semiconductor substrate 101 or the second semiconductor layer 109. Further, since the reflow process of the first interlayer insulating layer 111 is performed at a low temperature, degradation in the device characteristics may be prevented.

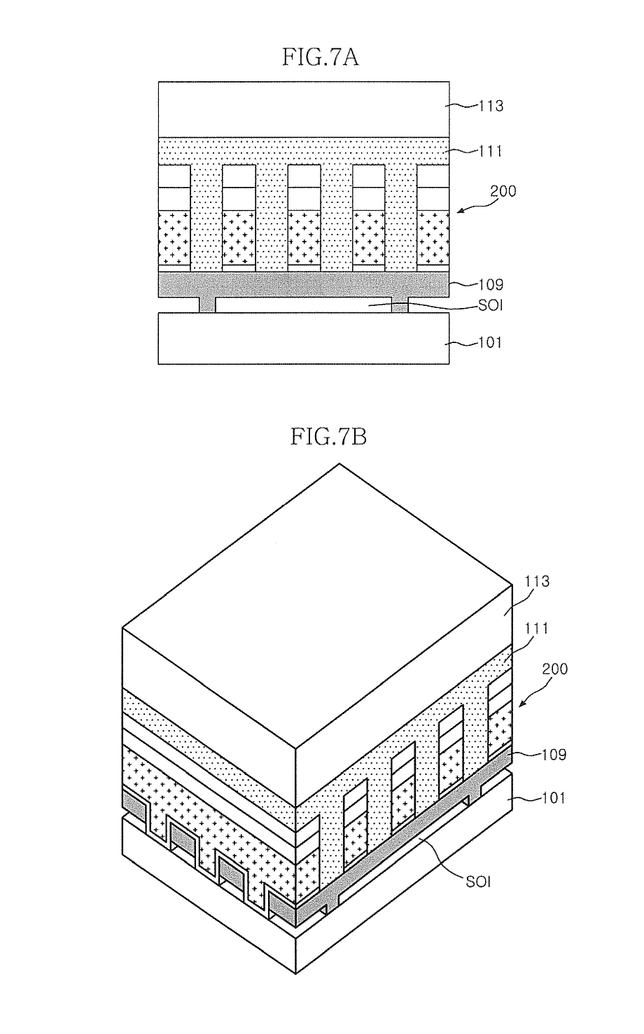

After the first interlayer insulating layer 111 is formed, a second interlayer insulating layer 113 is formed on the semiconductor substrate including the first interlayer insulating layer 111, as illustrated in FIGS. 7A and 7B. The second interlayer insulating layer 113 is formed to a thickness greater than or equal to a height of a step between a cell area and a peripheral area for a planarization process to uniformity of height between the cell area and the peripheral area. The second interlayer insulating layer 113 may be formed of an oxide layer formed by high density plasma (HDP) deposition. However, the second interlayer insulating layer 113 is not limited thereto.

Alternatively, before the forming of the first interlayer insulating layer 111, a source region and a drain region may be formed by exposing the active region at both sides of the gate structure 200 and implanting impurities into the exposed active region.

Therefore, the semiconductor apparatus formed as described above includes the second semiconductor layer 109, which includes the active region that extends in a first direction and that is electrically connected to the semiconductor substrate 101 and a portion that is disposed over the semiconductor substrate 101 in a floating state. The word line 200 is formed on the active region 109 in a direction perpendicular to the first direction, and the word line 200 surrounds a top and a side of the active region (that is, the second semiconductor layer 109). Junction regions are formed in the active region at both sides of the word line 200, and an SOI region having an air gap is formed in a floating region between the semiconductor substrate 101 and the active region.

A memory cell may be formed on the horizontal channel transistor fabricated as described above. For example, an electrode and a data storage electrically connected to the drain region may be formed on the drain region and a bit line electrically connected to the data storage material may be formed.

The data storage material may include a phase-change material, but the data storage material is not limited thereto. Any memory cell which may use the horizontal channel transistor as a selection device may be applied.

The above exemplary implementation is illustrative and not limitative. Various alternatives and equivalents are possible. The invention is not limited by the implementation described herein. Nor is the invention limited to any specific type of semiconductor device. Other additions, subtractions, or modifications are obvious in view of the present disclosure and are intended to fall within the scope of the appended claims.

What is claimed is:

1. A semiconductor apparatus, comprising:
a semiconductor substrate;
a semiconductor layer extending along the substrate in a first direction and connecting to the semiconductor substrate, the semiconductor layer having a portion that connects to the semiconductor substrate, and a portion that does not connect to the semiconductor substrate and forms an active region floating over the semiconductor substrate;
a word line formed on the active region and extending in a direction perpendicular to the first direction;
junction regions formed in the active region at both sides of the word line; and
an air gap formed in a floating region between the semiconductor substrate and the active region.

2. The semiconductor apparatus of claim 1, wherein the word line surrounds a top and a side of the active region.

3. A method of fabricating a semiconductor apparatus, the method comprising:
forming a sacrificial layer on a semiconductor substrate;
forming a semiconductor layer on the sacrificial layer;
forming, through the sacrificial layer, a source post connecting the semiconductor layer to the semiconductor substrate;
patterning the semiconductor layer to define an active region extending in a first direction;
forming, in a direction perpendicular to the first direction, a gate structure on the active region;
removing the sacrificial layer to form a silicon-on-insulating (SOI) region between the semiconductor layer and the semiconductor substrate; and
forming an interlayer insulating layer in a space between the gate structure and an adjacent gate structure to form an air gap in the SOI region.

4. The method of claim 3, wherein the forming the semiconductor layer includes:
sequentially forming the sacrificial layer and a first semiconductor layer on the semiconductor substrate;
patterning predetermined portions of the first semiconductor layer and the sacrificial layer to form a hole exposing a surface of the semiconductor substrate; and
growing the first semiconductor layer to form a source post filling the hole.

5. The method of claim 3, wherein the forming the gate structure further comprises:
forming the gate structure to surround a top and a side of the active region.

6. The method of claim 3, wherein the forming an interlayer insulating layer comprises:
forming a borophosphosilicate glass (BPSG) oxide layer.

7. The method of claim 6, wherein the forming a BPSG oxide layer further comprises:
forming a BPSG oxide layer having concentrations of boron (B) ions and phosphorous (P) ions is in a range of about 4 wt % to about 6 wt %.

8. The method of claim 3, further comprising:
wet annealing the interlayer insulating layer at a temperature of about 700° C. to about 750° C.
